(19) United States
(12) Patent Application Publication
(10) Pub. No.: US 2017/0125319 A1
(43) Pub. Date: May 4, 2017

(54) ELECTRONIC COMPONENT

(71) Applicant: ROHM CO., LTD., Kyoto (JP)

(72) Inventor: Hideaki YANAGIDA, Kyoto (JP)

(73) Assignee: ROHM CO., LTD., Kyoto (JP)

(21) Appl. No.: 15/340,915

(22) Filed: Nov. 1, 2016

(30) Foreign Application Priority Data
Nov. 4, 2015 (JP) 2015-216804

(51) Int. Cl. H01L 23/31; H01L 21/48; H01L 23/00

(52) U.S. Cl. CPC H01L 23/3121; H01L 24/05; H01L 24/13; H01L 24/11; H01L 24/03; H01L 21/4853; H01L 2224/0501

(57) ABSTRACT

The present invention provides an electronic component in which a molding resin completely fills the space between a chip component and a mounting substrate, thereby avoiding the corrosion of the chip component and mounting substrate. The electronic component includes an interposer as an example of a mounting substrate and a chip component. The interposer is disposed with a first wiring film and a second wiring film. The chip component is interposed between a first connection electrode and a second connection electrode so as to electrically and mechanically connect the first wiring film and the second wiring film. The first connection electrode and the second connection electrode are shaped as pins mounted upright from the first wiring film and second wiring film toward the chip component such that the chip component floats above the interposer and is connected to the first wiring film and the second wiring film.

### BACKGROUND

The present disclosure is related to an electronic component.

Generally, a printed wiring substrate is mounted with chip components having a single function (such as resistors, capacitors, wires, or diodes (including transistors)) or chip components with multiple functions integrated in a complicated way. The wiring configuration of the printed wiring substrate generally depends on the distance between electrodes of the chip components; however, there are cases where it is necessary that the wiring distance of the printed wiring substrate is greater than the distance between electrodes of the chip components in order to properly configure the wiring layout. In such cases, the chip component is mounted on the printed wiring substrate via a mounting substrate for adjusting the distance (also known as an intermediary layer).

Patent Literature 1 discloses one example of the above-mentioned configuration. Patent literature 1 discloses a semiconductor package that comprises a mounting substrate, disposed with solder pads; a chip component, comprising a metal bump, wherein the chip component is mounted on the mounting substrate via the solder pad that embeds the metal bump into the mounting substrate; and a molding resin, configured to seal the chip component.

### PRIOR TECHNICAL LITERATURE

[Patent literature 1] Japanese patent laid-open publication No. JP774194A.

[Patent literature 2] Japanese patent No. 2009260255B.

### BRIEF SUMMARY OF THE INVENTION

### Problems to be Solved in the Present Invention

In the semiconductor package disclosed in Patent literature 1, since the chip component is mounted on the mounting substrate via the solder pad that embeds the metal bump into the mounting substrate, the space between the chip component and the mounting substrate is very limited. Accordingly, it is possible that the molding resin in the space between the chip component and the mounting substrate is insufficient, resulting in pores (voids) in said space. The voids in said space may allow moisture to be retained in the voids, causing the erosion of the chip component or the mounting substrate.

It is known in the related art to use the underfill through capillary action to allow the molding resin to flow into the space between the chip component and the mounting substrate (see, for example, Patent literature 2). However, in the case where the space between the chip component and the mounting substrate is very limited, this method cannot effectively avoid the formation of voids.

In view of the foregoing, one purpose of the present invention is to provide an electronic component that allows for a desirable sealing of the molding resin in the space between the chip component and the mounting substrate, thereby advantageously avoiding the corrosion of the chip component and the mounting substrate.

### Technical Means for Solving Problems

The electronic component of the present invention comprises: a mounting substrate, disposed with a wiring film; a chip component, electrically and mechanically connected to the wiring film; and a connection electrode, disposed between the wiring film and the chip component so that the chip component floats above the mounting substrate and is connected with the wiring film via the connection electrode, wherein the connection electrode is shaped as a pin mounted upright from the wiring film toward the chip component.

### Effects of the Present Invention

In this electronic component, since the chip component is connected to the wiring film in a manner floating over the mounting substrate by means of the connection electrode, it is possible to create, between the chip component and the mounting substrate, a space sufficient for the filling of the molding resin. In this way, it is feasible to fill, adequately, molding resin into the space between the chip component and the mounting substrate, thereby avoiding the formation of voids between the chip component and the mounting substrate. As a result, the problem associated with the retention of moisture in the voids can be eliminated; hence, the corrosion of the chip components and the mounting substrate is also avoided.

### BRIEF DESCRIPTION OF THE DRAWINGS

FIG. 1 is a top view of an electronic component according to one embodiment of the present invention.

FIG. 2 is a longitudinal-sectional view taken along the line II-II in FIG. 1.

FIG. 3 is a partial expanded view illustrating the portion marked with the dashed line III in FIG. 2.

FIG. 4 is a partial expanded cross-sectional view illustrating the portion marked with the dashed line IV in FIG. 2.

FIG. 5 is a further expanded cross-sectional view illustrating the terminal electrode of FIG. 4.

FIG. 6 is a flow chart illustrating an example of the manufacturing method of the electronic component of FIG. 1.

FIG. 7A is an expanded cross-sectional view corresponding to a portion of FIG. 3, and illustrates one step of the manufacturing method illustrated in FIG. 6.

FIG. 7B is a cross-sectional view illustrating the next step of FIG. 7A.

FIG. 7C is a cross-sectional view illustrating the next step of FIG. 7B.

FIG. 7D is a cross-sectional view illustrating the next step of FIG. 7C.

FIG. 7E is a cross-sectional view illustrating the next step of FIG. 7D.

FIG. 7F is a cross-sectional view illustrating the next step of FIG. 7E.

FIG. 8A is an expanded cross-sectional view corresponding to a portion of FIG. 4, and illustrates one step of the manufacturing method illustrated in FIG. 6.

FIG. 8B is a cross-sectional view illustrating the next step of FIG. 8A.

FIG. 8C is a cross-sectional view illustrating the next step of FIG. 8B.

FIG. 8D is a cross-sectional view illustrating the next step of FIG. 8C.

FIG. 8E is a cross-sectional view illustrating the next step of FIG. 8D.

FIG. 8F is a cross-sectional view illustrating the next step of FIG. 8E.

### DETAILED DESCRIPTION

The embodiments of the present disclosure are specifically discussed below and make reference to the drawings.

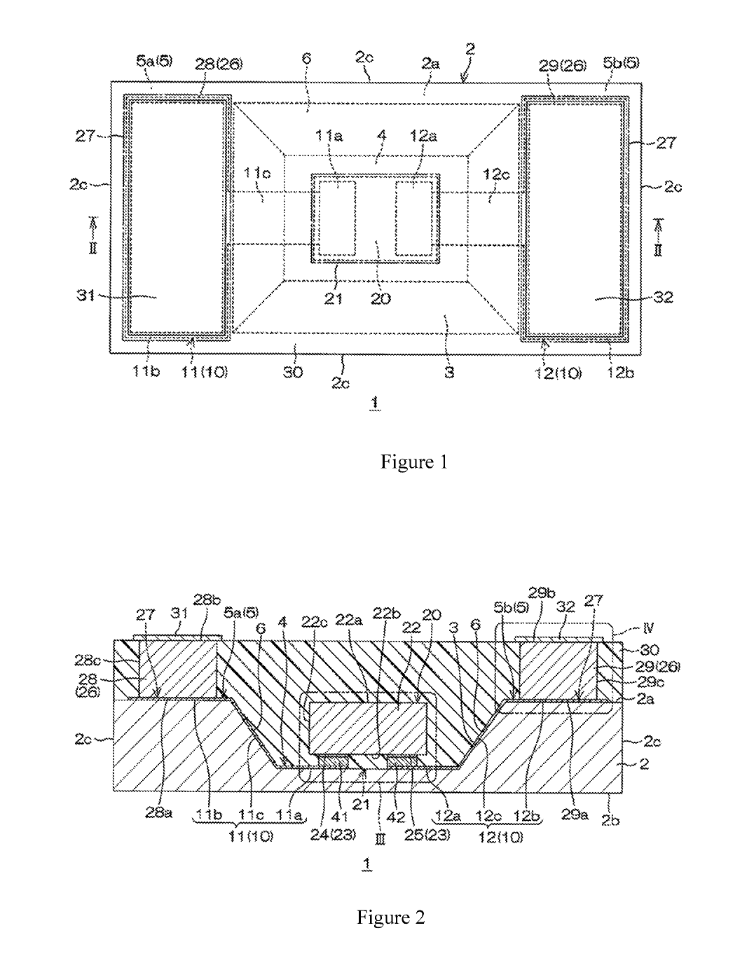

FIG. 1 is a top view of an electronic component 1 according to one embodiment of the present invention. FIG. 2 is a longitudinal-sectional view taken along the line II-II in FIG. 1.

The electronic component 1, which is an example of the mounting substrate according to the present invention, includes an interposer 2 made of silicon. Further, the interposer 2 can be made of an organic material such as epoxy or acrylic resins. Alternatively, the interposer 2 can be made of an inorganic material such as glass (SiO₂). The interposer 2, when viewed from the top, has a rectangular shape, and has a pair of main surfaces 2a, 2b, and four lateral faces 2c that connect the pair of main surfaces 2a, 2b. A recess 3 is formed at the central portion of main surface 2a of the interposer 2. The recess 3 is one-step recessed toward another main surface 2b. The recess 3 is rectangular when viewed from the top. The main surface 2b of the interposer 2 is flat.

On the main surface 2a of the interposer 2, the recess 3 has a low portion 4 that is rectangular in shape when viewed from the top and a high portion 5 that is elevated in relative to the low portion 4. The high portion 5 is a rectangular ring when viewed from the top. The high portion 5 comprises a first region 5a and a second region 5b, disposed at two ends of the longer sides, that are paired and rectangular in the top view. A low portion 4 is sandwiched by a first region 5a and a second region 5b. Surfaces of the low portion 4 and the high portion 5 are parallel to each other. A connection portion 6, disposed between the low portion 4 and the high portion 5, is disposed to connect the low portion 4 and the high portion 5. The recess 3, when viewed in the sectional view, tapers from the high portion 5 toward the low portion 4 so that the width of the opening narrows gradually. Accordingly, the connection portion 6 is a slanted surface.

Wiring films 10 containing for example, aluminum, are disposed on the main surface 2a of the interposer 2. The wiring films 10 include a first wiring film 11 and a second wiring film 12 which are arranged in a pair.

The first wiring film 11 is disposed to extend from the low portion 4 toward the first region 5a of the high portion 5. The first wiring film 11 includes a first pad 11a at the low portion 4, and a second pad 11b at the first region 5a of the high portion 5. The first wiring film 11 further includes a connection portion 11c, which extends on the connection portion 6. The connection portion 11c connects the first pad 11a and the second pad 11b. In the present embodiment, the first pad 11a, when viewed from the top, is formed as a rectangle and extends in the direction of the shorter sides of the interposer 2. In the present embodiment, the second pad 11b, when viewed from the top, is formed as a rectangle and extends in the direction of the shorter sides of the interposer 2.

The second wiring film 12 is disposed to extend from the low portion 4 toward the second region 5b of the high portion 5. The second wiring film 12 includes a first pad 12a at the low portion 4, and a second pad 12b at the second region 5b of the high portion 5. The second wiring film 12 further includes a connection portion 12c, which extends on the connection portion 6. The connection portion 12c connects the first pad 12a and the second pad 12b. In the present embodiment, the first pad 12a, when viewed from the top, is formed as a rectangle and extends in the direction of the shorter sides of the interposer 2. In the present embodiment, the second pad 12b, when viewed from the top, is formed as a rectangle and extends in the direction of the shorter sides of the interposer 2.

A chip mounting region 21 for mounting the chip component 20 is formed at a surface of the low portion 4 of the interposer 2. The mounting is through the first pad 11a of the first wiring film 11 and the first pad 12a of the second wiring film 12. Electrode arrangement regions 27 for arranging some terminal electrodes 26 are disposed at the surfaces of the first region 5a and second region 5b of the high portion 5 in the interposer 2. The arrangement is through the second pad 11b of the first wiring film 11 and the second pad 12b of the second wiring film 12.

The chip component 20 mounted in the chip mounting region 21 comprises a chip body 22 that is substantially rectangular. The chip body 22 comprises a pair of main faces 22a, 22b and four lateral faces 22c that connect the pair of main faces 22a, 22b. The main face 22b of the chip body 22 is configured as the mounting surface (hereinafter, referred to as “mounting surface 22b”) that is facing the interposer 2 when mounting the chip component 20 into the interposer 2.

The chip body 22 can be made from insulating materials (such as ceramics) or semiconductor materials (such as silicon). The mounting surface 22b of the chip component 20 can also be made from insulating material or semiconductor material, from which the chip body 22 is formed. Further, in some embodiments, by covering the main face 22b of the chip body 22 with an insulating film or resin film, the mounting surface 22b of the chip component 20 can also be formed from a portion of the insulating film or a portion of the resin film.

The chip component 20 can also be a discrete component that may include a single-function component, such as a resistor, capacitor, coil, or diode (including transistor). Alternatively, the chip component 20 can be a chip component with multiple functions, which comprises several single-function components such as resistor, capacitor, coil, or diode (comprising transistors) in various combinations. In some embodiments, there may be a Central Processing Unit (CPU) or memory chip consisting of integrated circuits.

In an embodiment, mounting electrode having several bump electrodes 23 are formed at the two ends of the longer sides of the chip body 22. In the embodiment, the bump electrodes 23 include a first bump electrode 24 and a second bump electrode 25 arranged in a pair. The chip component 20 is face-down mounted on the interposer 2 by mechanically and electrically connecting the first bump electrodes 24 with the first wiring film 11, and mechanically and electrically connecting the second bump electrodes 25 with the second wiring film 12. Moreover, the bump electrodes 23 may include a laminate layer having Au film, Pd film, or Ni film, which are sequentially deposited from the mounting surface 22b side of the chip component 20.

The terminal electrodes 26 are disposed in the electrode arrangement region 27 and include a first terminal electrode 28 and a second terminal electrode 29 arranged in a pair. The first terminal electrode 28 has a block, pillar or column shape, and is electrically and mechanically connected to the second pad 11b of the first wiring film 11. The first terminal electrode 28 includes an end surface 28a, connected with the second pad 11b of the first wiring film 11, and an end surface 28b. Surface 28b and surface 28a are on opposite sides. Surface 28b is configured for external connection. A lateral face 28c is configured to connect each of the peripheral portions of the surface 28a and the surface 28b.

The second terminal electrode 29 has a block, pillar or column shape, and is electrically and mechanically connected to the second pad 12b of the second wiring film 12. The second terminal electrode 29 includes an end surface 29a, connected with the second pad 12b of the second wiring film 12; and an end surface 29b. Surface 29b and surface 29a are on opposite side. Surface 29b is configured for external connection. Lateral face 29c is configured to connect each of the peripheral portions of surface 29a and surface 29b.

A molding resin 30 is formed on the main surface 2a of the interposer 2 and leaves an end surface 28b of the first terminal electrode 28 and an end surface 29b of the second terminal electrode 29 exposed. A surface of the molding resin 30 is formed as a flat surface that is parallel to another main surface 2b of the interposer 2. Additionally, the surface of the molding resin 30 is level with an end surface 28b of the first terminal electrode 28 and end surface face 29b of the second terminal electrode 29. Also, the lateral face of the molding resin 30 is coplanar with the lateral face 2c of the interposer 2.

A first conductive bonding film 31 is formed on a molding resin 30 and cove surface 28b of the first terminal electrode 28. A second conductive bonding film 32 is formed on the molding resin 30 to cover a surface 29b of the second terminal electrode 29. The first conductive bonding film 31 and the second conductive bonding film 32 can be a solder film comprising Sn, for example.

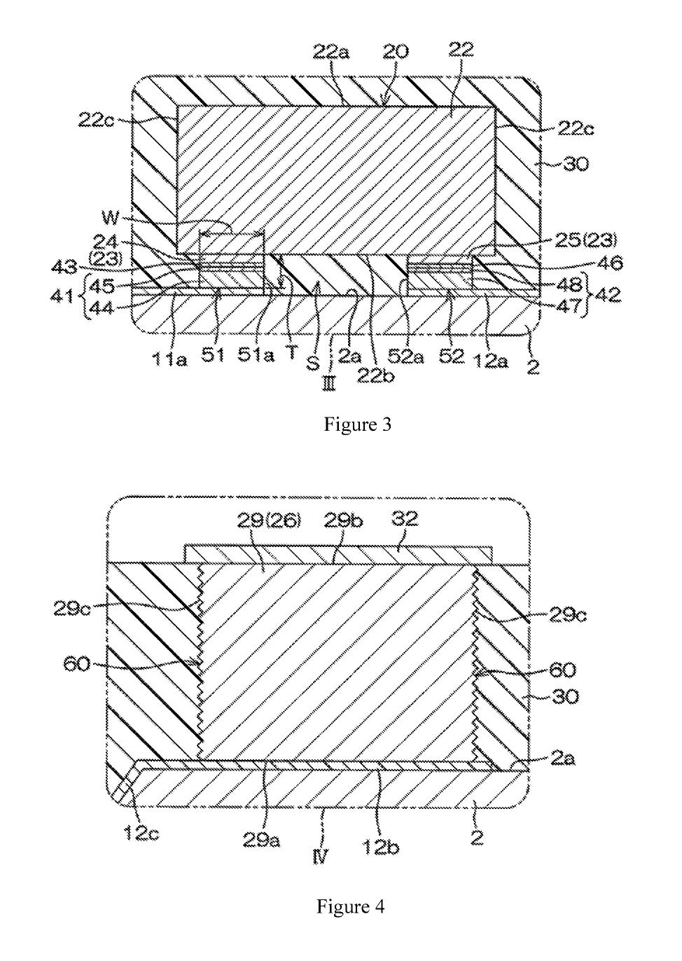

FIG. 3 is a partial expanded view illustrating the portion marked with the dashed line III in FIG. 2.

Referring to FIG. 3, one feature of the present invention is to have a first connection electrode 41 disposed between the first bump electrodes 24 of the chip component 20 and the first wiring film 11 (the first pad 11a), and have a second connection electrode 42 disposed between the second bump electrodes 25 of the chip component 20 and the second wiring film 12 (the first pad 12a). Both the first connection electrode 41 and the second connection electrode 42 are, respectively, shaped as pins and standing from the first wiring film 11 and the second wiring film 12 and toward the chip component 20. Therefore, the chip component 20 is connected with the first wiring film 11 and the second wiring film 12 but are floating above the interposer 2.

The present invention, by employing the first connection electrode 41 and the second connection electrode 42, allows the molding resin 30 to adequately seal the chip component 20, and thereby inhibits corrosion of the chip component 20 and the interposer 2.

More specifically, the first connection electrode 41 has a block, pillar or column shape, and is formed on the first pad 11a so as to connect with the first pad 11a of the first wiring film 11. The second connection electrode 42 is shaped to have the same shape as the first connection electrode 41, and is formed on the first pad 12a so as to connect with the first pad 12a of the second wiring film 12.

As viewed from FIG. 3, the first connection electrode 41 and the second connection electrode 42 are preferably formed with an aspect ratio R of no greater than 1 (R≦1), wherein the aspect ratio R is defined as the ratio of the height (T) to the width (W). By using an aspect ratio R of less than 1 (R≦1), it is feasible to form the first connection electrode 41 and second connection electrode 42 on the first pad 11a of the first wiring film 11 and the first pad 12a of the second wiring film 12 with a desirable balance.

The first connection electrode 41 is mechanically and electrically connected to the first bump electrode 24 of the chip component 20 via the first conductive bonding layer 43. The first conductive bonding layer 43 may be a solder layer comprising Sn—Sb alloy, for example. In such configuration, the first connection electrode 41 includes a main body 44 and a barrier layer 45, which is disposed between the main body 44 and the first conductive bonding layer 43. The main body 44 includes, for example, a Cu plating layer. On the other hand, the barrier layer 45 includes, for example, a Ni plating layer, which is configured to suppress diffusion of the bonding material of the first conductive bonding layer 43 into the main body 44.

Similarly, the second connection electrode 42 is mechanically and electrically connected to the second bump electrodes 25 of the chip component 20 via the second conductive bonding layer 46. The second conductive bonding layer 46 may be a solder layer comprising Sn—Sb alloy. In such configuration, the second connection electrode 42 comprises a main body 47 and a barrier layer 48, which is disposed between the main body 47 and the second conductive bonding layer 46. The main body 47 includes, for example, a Cu plating layer. On the other hand, the barrier layer 48 includes, for example, a Ni plating layer, which is configured to suppress diffusion of the bonding material of the second conductive bonding layer 46 into the main body 47.

Further, both the first bump electrodes 24 and the second bump electrodes 25 of the chip component 20 are disposed to protrude from the mounting surface 22b of the chip body 22 toward the interposer 2 side. Accordingly, the connecting portion of the first bump electrodes 24 and the first conductive bonding layer 43, and the connecting portion of the second bump electrodes 25 and the second conductive bonding layer 46, are both proximal to interposer 2 relative to the mounting surface 22b of the chip component 20.

The chip component 20 is sealed by filling the space S between the chip component 20 and the interposer 2 with the molding resin 30 to a height. The first connection electrode 41 and the second connection electrode 42 allow the chip component 20 to connect to the interposer 2. The molding resin 30 filled in the space S between the chip component 20 and the interposer 2 covers the whole area of the mounting surface 22b of the chip component 20 and the main surface 2a of the interposer 2. Moreover, the molding resin 30 filled in the space S covers the side portion 51a of a first electrode column 51 formed by the first bump electrodes 24, the first connection electrode 41 and the first conductive bonding layer 43. The molding resin 30 also covers the side portion 52a of a second electrode column 52 formed by the second bump electrodes 25, the second connection electrode 42 and the second conductive bonding layer 46.

In the present invention, the first connection electrode 41 and the second connection electrode 42 provide a space S between the chip component 20 and the interposer 2. This allows the molding resin 30 to be fully filled into the space S between the chip component 20 and the interposer 2, thereby inhibiting the formation of any voids between the chip component 20 and the interposer 2. As a result, the problem associated with retained moisture in the voids is eliminated, which in turn avoids the corrosion of the chip component 20 and the interposer 2.

In particular, in the present invention, since the molding resin 30 covers the side portion 51a of the first electrode column 51 and the side portion 52a of the second electrode column 52, the corrosion of these electrode materials can be avoided. As a result, the deterioration of the electrical characteristics of the first electrode column 51 and the second electrode column 52 can be effectively prevented.

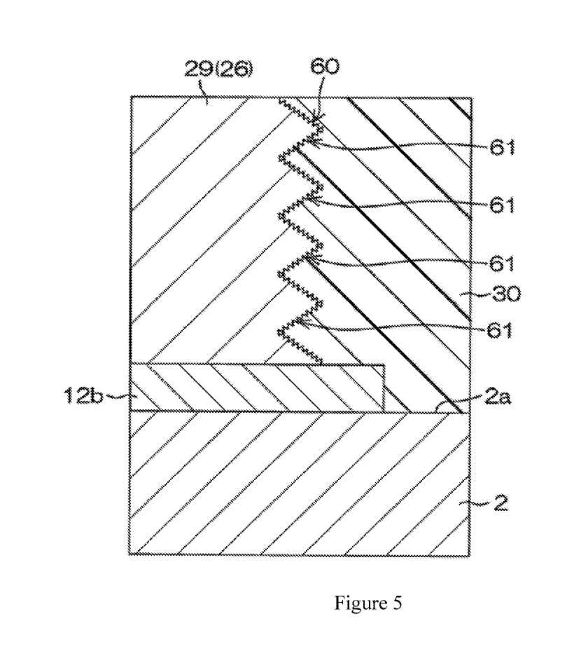

FIG. 4 is a partial expanded cross-sectional view illustrating the portion marked with the dashed line IV in FIG. 2. FIG. 5 is a further expanded cross-sectional view illustrating the terminal electrode 26 of FIG. 4. Further, since the structure of the first terminal electrode 28 is substantially the same as that of the second terminal electrode 29, only the structure of the second terminal electrode 29 is depicted in FIG. 4 and FIG. 5.

Referring to FIG. 4 and FIG. 5, another feature of the present invention is that the lateral surface 28c of the first terminal electrode 28 and the lateral surface 29c of the second terminal electrode 29 are roughened. In the present invention, roughening the lateral surface 28c of the first terminal electrode 28 and the lateral surface 29c of the second terminal electrode 29 can improve the binding strength (i.e., the adhesion and anchoring effect) between the first and second terminal electrodes 28, 29 and the molding resin 30, which is filled around the periphery of the first terminal electrode 28 and the second terminal electrode 29. Therefore, the detachment (falling off) of the first terminal electrode 28 and the second terminal electrode 29 from the molding resin 30 can be avoided.

Roughening completely the lateral surface 28c of the first terminal electrode 28 and the lateral surface 29c of the second terminal electrode 29 forms a first corrugated surface 60. Referring to FIG. 5, within each recessed portion of the first corrugated surface 60, there is a second corrugated surface 61. The second corrugated surface 61 has an uneven structure that is finer than that of the first corrugated surface 60. That is, roughening the lateral surfaces 28c, 29c to create a combination of relatively coarse and fine uneven structures can increase the binding strength with the molding resin 30 through these uneven structures.

In this configuration, the molding resin 30 flows into the recessed portion through the first corrugated surface 60, and further contacts the second corrugated surface 61 in the recessed portion. In this way, it is feasible to prevent the first terminal electrode 28 and the second terminal electrode 29 from detaching from (falling off) the molding resin 30.

In view of the foregoing, the present embodiment provides an electronic component 1, which allows for a satisfactory filling of the molding resin 30 into the space S between the chip component 20 and the interposer 2, thereby avoiding the corrosion of the chip component 20 and the interposer 2. Also, the present embodiment provides an electronic component 1, which prevents the first terminal electrode 28 and the second terminal electrode 29 from detaching from (falling off) the molding resin 30.

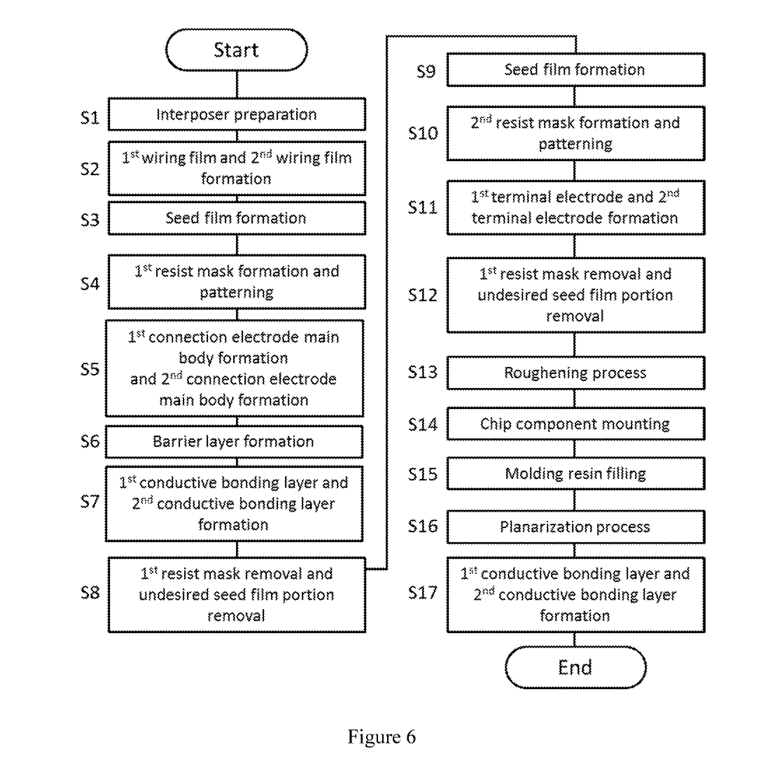

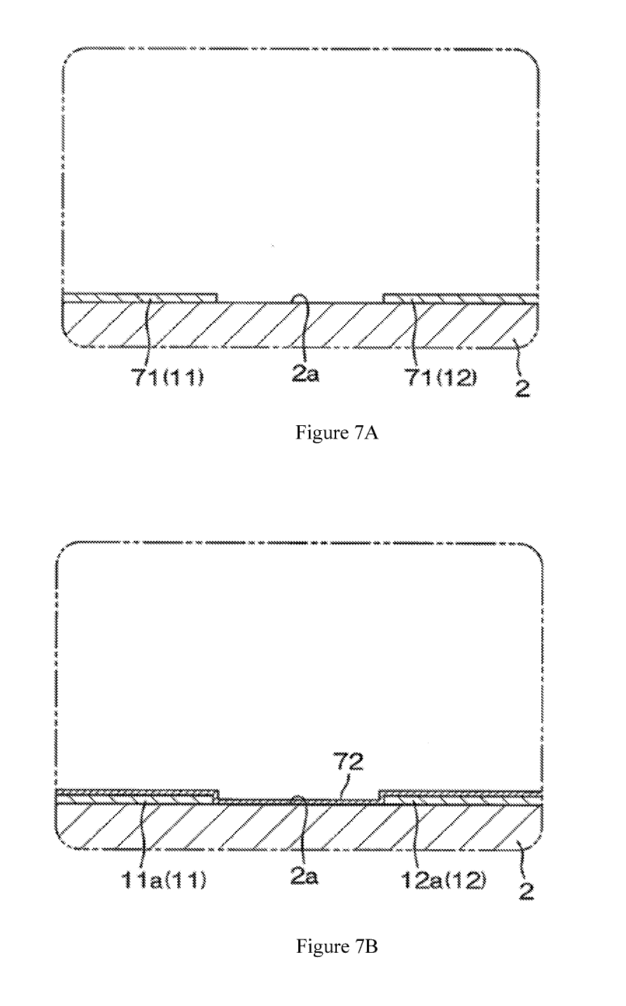

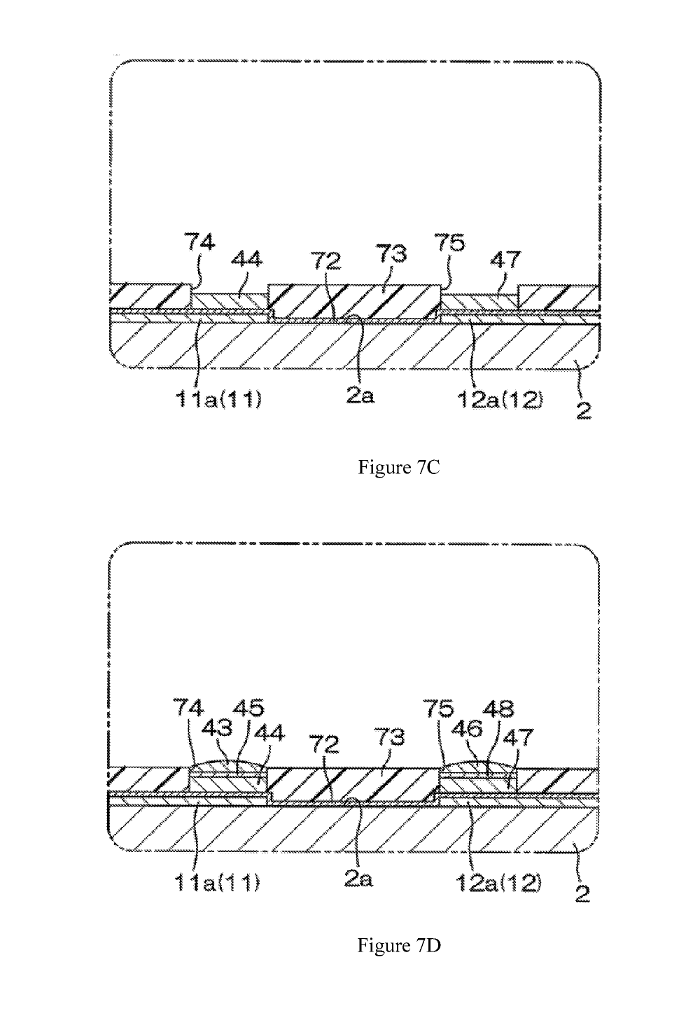

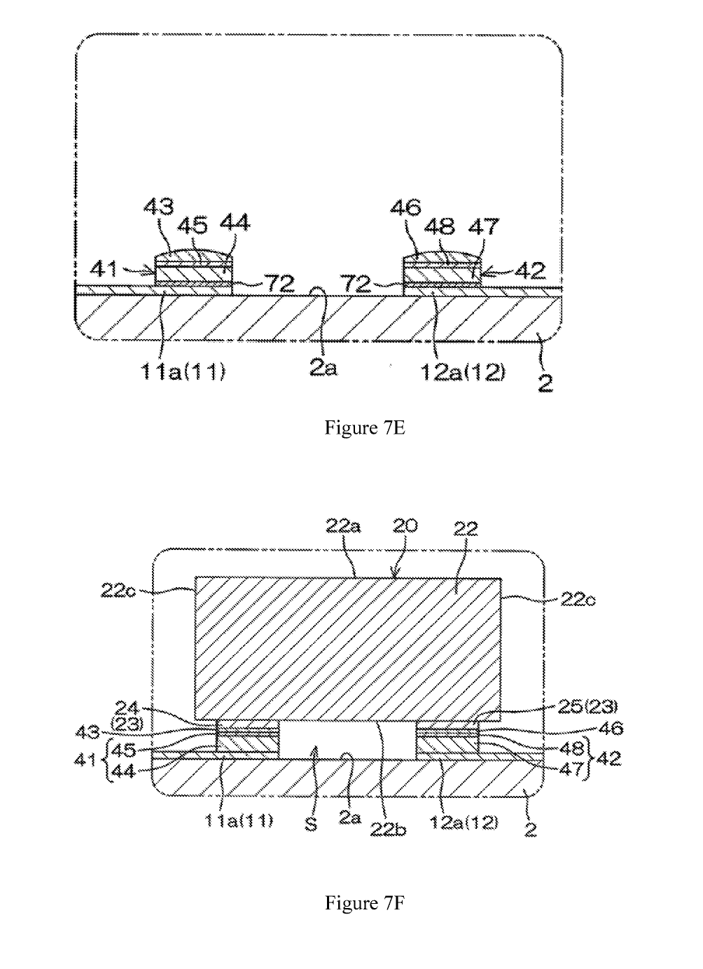

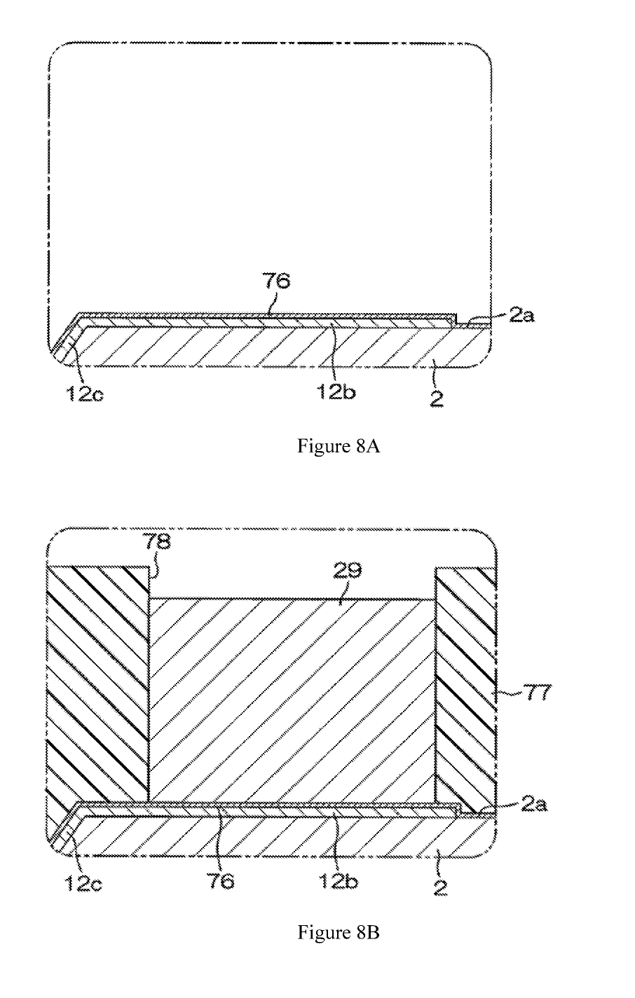

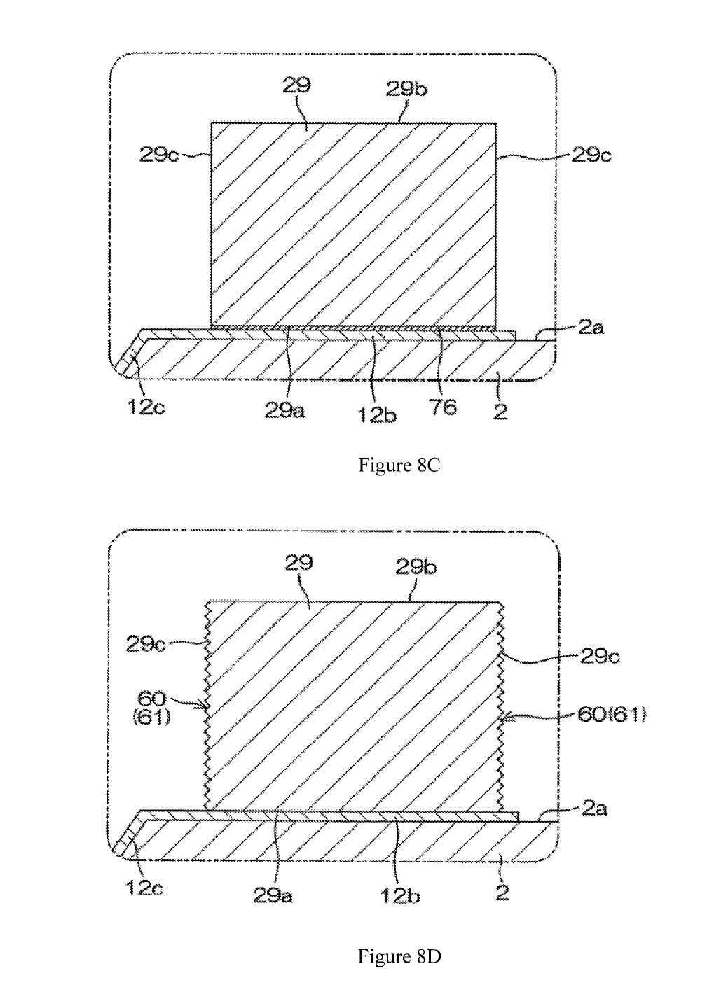

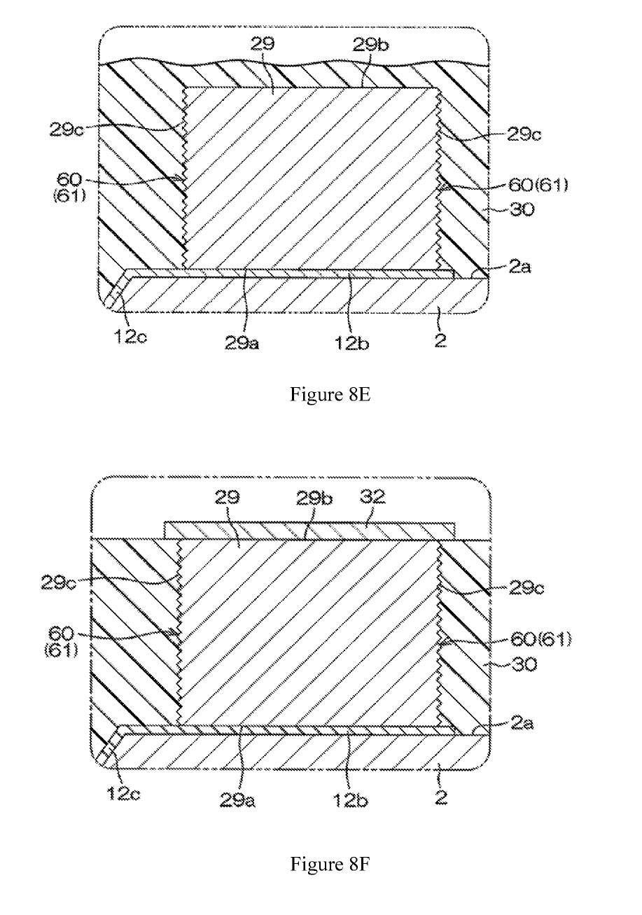

FIG. 6 is a flow chart illustrating an example of the manufacturing method of the electronic component 1 of FIG. 1. FIG. 7A to FIG. 7F are expanded cross-sectional views corresponding to a portion of FIG. 3, and respectively illustrate one step of the manufacturing method illustrated in FIG. 6. FIG. 8A to FIG. 8F are expanded cross-sectional views corresponding to a portion of FIG. 4, and respectively illustrate one step of the manufacturing method illustrated in FIG. 6.

Hereinafter, proper reference is made to FIG. 6, FIG. 7A to FIG. 7F, and FIG. 8A to FIG. 8F, to describe the manufacturing method of the electronic component 1.

Referring to FIG. 7A, when manufacturing the electronic component 1, an interposer 2 made of silicon is provided (Step S1), wherein a recess 3 (also referring to FIG. 1) is formed in the main surface 2a of the interposer 2. Next, an aluminum film 71 covering the whole extent of the main surface 2a of the interposer 2 is formed (Step S2). The aluminum film 71 can be formed by, for example, sputtering. Thereafter, the aluminum film 71 is selectively patterned to form the first wiring film 11 and the second wiring film 12.

Referring to FIG. 7B, copper is deposited on the main surface 2a of the interposer 2 by, for example, sputtering, so as to cover the first pad 11a of the first wiring film 11 and the first pad 12a of the second wiring film 12 (Step S3). In this way, a Cu seed film 72 covering the first pad 11a of the first wiring film 11 and the first pad 12a of the second wiring film 12 is formed.

Referring to FIG. 7C, a first photoresist mask 73 covering the whole extent of the main surface 2a of the interposer 2 is formed (Step S4). Thereafter, the first photoresist mask 73 is exposed and developed in such a way that the areas configured to form the first connection electrode 41 and the second connection electrode 42 are exposed. In this way, openings 74, 75 are formed in pairs in the first photoresist mask 73.

Next, Cu is plated and grown on the Cu seed film 72 exposed from the pair of openings 74, 75 through, for example, electroplating (Step S5). In this step, Cu is plated and grown until the growth plane of Cu reaches a depth that is at the middle portion in the thickness direction of the pair of openings 74, 75. In this way, the main body 44 of the first connection electrode 41 and the main body 47 of the second connection electrode 42 are formed. Also, in this step, the main body 44 of the first connection electrode 41 and the main body 47 of the second connection electrode 42, as well as the Cu seed film 72, are integrally formed.

Referring to FIG. 7D, Ni is plated and grown on the main body 44 by, for example, electroplating (Step S6). The main body 44 is exposed via the pair of openings 74, 75. In this step, Ni is plated and grown until the growth plane of Ni reaches a depth that is slightly more proximal to the interposer 2 than the surface of the first photoresist mask 73 is. In this way, a barrier layer 45 is formed.

Next, an alloy of Sn—Sb is plated and grown on the barrier layer 45 by, for example, electroplating (Step S7). The barrier layer 45 is exposed via the pair of openings 74, 75. In this step, the Sn—Sb alloy is plated and grown until the growth plane of Sn—Sb reaches a level that is more elevated than the surface of the first photoresist mask 73. In this way, a first conductive bonding layer 43 and a second conductive bonding layer 46 are formed.

Referring to FIG. 7E, the first photoresist mask 73 is subsequently removed by, for example, etching. The undesired portion of the Cu seed film 72 is removed by etching (Step S8). In this way, the first connection electrode 41 is formed on the first wiring film 11, and the second connection electrode 42 is formed on the second wiring film 12.

Referring to FIG. 8A, copper is deposited on the main surface 2a of the interposer 2 by, for example, sputtering, so as to cover the second pad 11b of the first wiring film 11 and the second pad 12b of the second wiring film 12. In this way, a Cu seed film 76 covering the second pad 11b of the first wiring film 11 and the second pad 12b of the second wiring film 12 is formed on the main surface 2a of the interposer 2 (Step S9).

Referring to FIG. 8B, a second photoresist mask 77 covering the whole extent of the main surface 2a of the interposer 2 is formed (Step S10). Next, the second photoresist mask 77 is exposed and developed in such a way that the areas configured to form the first terminal electrode 28 and the second terminal electrode 29 are exposed. In this way, a pair of openings 78 are formed in the first photoresist mask 77.

Next, Cu is plated and grown on a portion of the Cu seed film 76 by, for example, electroplating (Step S11). The portion of the Cu seed film 76 is exposed via the pair of openings 78. In this step, Cu is plated and grown until the growth plane of Cu reaches a depth that is at the level of the middle portion in the thickness direction of the pair of openings 78. In this way, the first terminal electrode 28 and the second terminal electrode 29 are integrally formed.

Referring to FIG. 8C, the second photoresist mask 77 is removed by, for example, etching. The undesired portion of the Cu seed film 76 is subsequently removed by etching (Step S12).

Referring to FIG. 8D, the lateral surface 28c of the first terminal electrode 28 and the lateral surface 29c of the second terminal electrode 29 are roughened (Step S13). As an example, the roughening process can be any of the following steps (1) to (3).

(1) Each of the lateral surfaces 28c, 29c can be roughened by subjecting the lateral surface 28c of the first terminal electrode 28 and the lateral surface 29c of the second terminal electrode 29 to wet-etching or plasma-etching.

(2) Alternatively, each of the lateral surfaces 28c, 29c can be roughened by subjecting it to a roughening process solution (such as “MoldPrep LF” manufactured by Atotech Japan K.K.), so that the lateral surface 28c of the first terminal electrode 28 and the lateral surface 29c of the second terminal electrode 29 are etched along the Cu grain boundary. The Cu grains constitute the first terminal electrode 28 and the second terminal electrode 29.

(3) After performing step (1), and the step (2) afterward, the roughening process to the lateral surface 28c of the first terminal electrode 28 and the lateral surface 29c of the second terminal electrode 29 is accomplished.

By performing one of the steps (1) to (3), in particular the step (2) or (3), it is feasible to adequately form the first corrugated surface 60 and the second corrugated surface 61 are formed at the lateral surface 28c of the first terminal electrode 28 and the lateral surface 29c of the second terminal electrode 29.

Referring to FIG. 7F, the chip component 20 is connected with the first connection electrode 41 and the second connection electrode 42 (Step S14). In this step, the chip component 20 is mounted face-down on the interposer 2 by mechanically and electrically connecting the first bump electrode 24 to the first wiring film 11, and by mechanically and electrically connecting the second bump electrode 25 to the second wiring film 12. In this step, a space S for the adequate filling of the molding resin 30 across the whole extent is allowed to be formed between the chip component 20 and the interposer 2 by utilizing the first connection electrode 41 and the second connection electrode 42.

Referring to FIG. 8E, molding resin 30 flows in to cover the whole extent of the main surface 2a of the interposer 2 (Step S15). In this step, the space S between the chip component 20 and the interposer 2 is filled with the molding resin 30 (reference is also made to FIG. 7F). Moreover, the molding resin 30 flows onto the main surface 2a of the interposer 2 to completely cover the external surface of the chip component 20, the external surface of the first terminal electrode 28, and the external surface of the second terminal electrode 29.

Referring to FIG. 8F, the surface of the molding resin 30 is subjected to planarization until the first terminal electrode 28 and the second terminal electrode 29 are exposed (Step S16). The surface of the molding resin 30 can be planarized by polishing or grinding. Next, Sn is plated and grown, for example, by electroplating, on the other end surface 28b of the first terminal electrode 28 and the other end face 29b of the second terminal electrode 29 that are exposed from the molding resin 30 (Step S17). In this way, a first conductive bonding film 31 covering end surface 28b of the first terminal electrode 28 and a second conductive bonding film 32 covering end surface 29b of the second terminal electrode 29 are formed on the molding resin 30. The electronic component 1 is formed accordingly.

In view of the foregoing, in the manufacturing method according to the present embodiment, the first connection electrode 41 and the second connection electrode 42 are formed on the interposer 2. The first connection electrode 41 and the second connection electrode 42 can also be formed at the side of the chip component 20. However, in this case, the number of manufacturing steps for the chip component 20 may increase. Further, to form the first connection electrode 41 and the second connection electrode 42 at the side of the chip component 20, these electrodes should be made smaller than the chip component 20, thereby increasing the difficulty of the manufacturing process.

Accordingly, in the manufacturing method according to the present embodiment, the first connection electrode 41 and the second connection electrode 42 are formed at the side of the interposer 2 which is larger in size than the chip component 20. Accordingly, it is not necessary to form the first connection electrode 41 and the second connection electrode 42 at the side of the chip component 20, and it is possible to avoid the increase in the manufacturing difficulty and prevent the increase of the number of the manufacturing steps of the chip component 20.

Also, in the manufacturing method according to the present embodiment, introducing the openings 74, 75 of the first photoresist mask 73 inhibits the first conductive bonding layer 43 and the second conductive bonding layer 46 on the first photoresist mask 73, and a sufficient amount of the first conductive bonding layer 43 and second conductive bonding layer 46 are formed. In particular, in the manufacturing method according to the present embodiment, the first conductive bonding layer 43 and the second conductive bonding layer 46 are more elevated formed than the surface of the first photoresist mask 73 (reference also made to FIG. 7D). In this way, the chip component 20 can be adequately connected with the first connection electrode 41 and the second connection electrode 42 (reference also made to FIG. 7F).

The present invention has been discussed above with referencing to particular embodiments; however, the present invention is not limited thereto; rather it can be implemented by other embodiments.

For example, in the above-mentioned embodiments, the main body 44 of the first connection electrode 41 and the main body 47 of the second connection electrode 42 both comprise a Cu-plated layer. However, the main body 44 of the first connection electrode 41 and the main body 47 of the second connection electrode 42 may also comprise a Ni-plated layer formed by, for example, electroplating. In this case, the main body 44 of the first connection electrode 41 and the main body 47 of the second connection electrode 42 may be directly connected to the first conductive bonding layer 43 and the second conductive bonding layer 46 without interposing Ni barrier layer 45 (Ni-plated layer) in between.

Moreover, in the above-mentioned embodiments, the second corrugated surface 61 formed in the recessed portion of first corrugated surface 60 of the first terminal electrode 28 and the second terminal electrode 29 is described. The second corrugated surface 61 has a finer roughened structure than the first corrugated surface 60. However, the second corrugated surface 61 can be a fine uneven surface formed by attaching insulating particles (e.g., SiO₂ particles) or conductive particles (e.g., Ni particles or Cu particles) to the surface of the first corrugated surface 60 by, for example, Chemical Vapor Deposition (CVD).

Further, in the above-mentioned embodiments, bump electrodes 23 (the first bump electrode 24 and the second bump electrode 25) are used as an example of the mounting electrode of the chip component 20. However, in the case where the mounting electrode is a terminal electrode for receiving the external power into the chip body 22, the mounting electrode can adopt any suitable form. For example, the mounting electrode can use a portion of the wiring layer formed on the mounting surface 22b of the chip body 22 (such as the uppermost wiring form on the top layer of the wiring layer). Also, the mounting electrode can use a portion of the redistribution layer connected with the wiring layer.

Moreover, various modifications can be made within the scope defined by the appended claims.

What is claimed is:

1. An electronic component, comprising:
a mounting substrate, disposed with a wiring film;
a chip component, electrically and mechanically connected to the wiring film; and
a connection electrode, disposed between the wiring film and the chip component so that the chip component floats above the mounting substrate and is connected to the wiring film via the connection electrode, and the connection electrode is shaped as a pin mounted upright from the wiring film toward the chip component.

2. The electronic component of claim 1, wherein when the connection electrode is sealed with a molding resin in the chip component, the chip component is connected with the mounting substrate at the height of a space that is filled with the molding resin between the chip component and the mounting substrate.

3. The electronic component of claim 1, wherein the chip component comprises a mounting electrode disposed on a mounting surface that is opposite to the mounting substrate, and
the connection electrode is configured to connect the mounting electrode of the chip component and the wiring film of the mounting substrate.

4. The electronic component of claim 3, wherein the mounting electrode of the chip component is disposed to protrude from the mounting surface and toward the mounting substrate.

5. The electronic component of claim 3, further comprising a conductive bonding material, wherein the conductive bonding material is configured to electrically and mechanically connect the mounting electrode of the chip component to the connection electrode.

6. The electronic component of claim 5, wherein the connection electrode comprises: a main body and a barrier layer, wherein the barrier layer is disposed between the main body and the conductive bonding material, and is configured to prevent the bonding material of the conductive bonding material from diffusing into the main body.

7. The electronic component of claim 1, wherein the connection electrode has a block, pillar or column shape, and is formed on the wiring film by connecting to the wiring film.

8. The electronic component of claim 1, further comprising a terminal electrode for external connection, wherein the terminal electrode is mounted upright on the wiring film and comprises: one terminal, connected with the wiring film; another terminal, opposite to said one terminal and configured for external connection; and a lateral surface connecting each of the peripheral portions of said one terminal and said another terminal.

9. The electronic component of claim 8, wherein the lateral surface of the terminal electrode is roughened.

10. The electronic component of claim 8, wherein the mounting substrate comprises a low portion and a high portion that is elevated upwards relative to the low portion; and
the low portion of the mounting substrate is disposed with a chip mounting area for mounting the chip component, and the high portion of the mounting substrate is disposed with an electrode arrangement region for arranging the terminal electrode.
